(19) United States
(12) Patent Application Publication
(10) Pub. No.: US 2022/0075008 A1
(43) Pub. Date: Mar. 10, 2022

(54) STRAY FIELD IMMUNE ANGLE SENSOR

(71) Applicant: Allegro MicroSystems, LLC, Manchester, NH (US)

(72) Inventor: Hernán D. Romero, Buenos Aires (AR)

(73) Assignee: Allegro MicroSystems, LLC, Manchester, NH (US)

(21) Appl. No.: 17/015,132

(22) Filed: Sep. 9, 2020

(51) Int. Cl. G01R 33/07; G01R 33/00; G01D 5/14

(52) U.S. Cl. CPC G01R 33/072; G01D 5/145; G01R 33/0029; G01R 33/0017

(57) ABSTRACT

An apparatus comprising: a ring magnet having first surface, a second surface, and a bore extending from the first surface to the second surface, the bore having a central longitudinal axis; a substrate disposed inside the bore, the substrate having a first axis and a second axis; a first group of magnetic field sensing elements that are formed on the substrate, the first group of magnetic field sensing elements including a first in plane magnetic transducer and a second magnetic field sensing element, the first magnetic field sensing element being aligned with the first axis and the second magnetic field sensing element being aligned with the second axis; and a second group of magnetic field sensing elements that are formed on the substrate, the second group of magnetic field sensing elements including a third magnetic field sensing element and a fourth magnetic field sensing element, the third magnetic field sensing element being aligned with the first axis, and the fourth MR element being aligned with the second axis.

### BACKGROUND

Magnetic field sensors employ a variety of types of magnetic field sensing elements, for example, Hall effect elements and magnetoresistance elements, often coupled to a variety of electronics, all disposed over a common substrate. A magnetic field sensing element (and a magnetic field sensor) can be characterized by a variety of performance characteristics, one of which is a sensitivity, which can be expressed in terms of an output signal amplitude versus a magnetic field to which the magnetic field sensing element is exposed. Some magnetic field sensors can detect a linear motion of a target object. Some other magnetic field sensors can detect a rotation of a target object. The accuracy with which magnetic field sensors detect an intended magnetic field can be adversely affected by the presence of stray magnetic fields (i.e., fields other than those intended to be detected).

### SUMMARY

According to aspects of the disclosure, an apparatus is provided, comprising: a ring magnet having first surface, a second surface, and a bore extending from the first surface to the second surface, the bore having a central longitudinal axis; a substrate disposed inside the bore of the ring magnet, the substrate having a first axis and a second axis that is orthogonal to the first axis, the first axis and the second axis being orthogonal to the central longitudinal axis of the bore; a first group of magnetic field sensing elements that are formed on the substrate, the first group of magnetic field sensing elements including a first magnetic field sensing element and a second magnetic field sensing element, the first magnetic field sensing element being aligned with the first axis and the second magnetic field sensing element being aligned with the second axis; and a second group of magnetic field sensing elements that are formed on the substrate, the second group of magnetic field sensing elements including a third magnetic field sensing element and a fourth magnetic field sensing element, the third magnetic field sensing element being aligned with the first axis, and the fourth magnetic field sensing element being aligned with the second axis.

According to aspects of the disclosure, an apparatus is provided, comprising: a substrate having a major planar surface, wherein the major planar surface has a first axis and a second axis that is orthogonal to the first axis; a first group of magnetic field sensing elements that are formed on the major planar surface of the substrate, the first group of magnetic field sensing elements including a first magnetic field sensing element and a second magnetic field sensing element, the first magnetic field sensing element being aligned with the first axis and the second magnetic field sensing element being aligned with the second axis; and a second group of magnetic field sensing elements that are formed on the major planar surface of the substrate, the second group of magnetic field sensing elements including a third magnetic field sensing element and a fourth magnetic field sensing element, the third magnetic field sensing element being aligned with the first axis, and the fourth magnetic field sensing element being aligned with the second axis, wherein each of the first magnetic field sensing element, the second magnetic field sensing element, and the third magnetic field sensing element, and the fourth magnetic field sensing element is formed on a periphery of the substrate.

According to aspects of the disclosure, an apparatus is provided, comprising: a substrate having a major planar surface, wherein the major planar surface has a first axis and a second axis that is orthogonal to the first axis; a first planar Hall element that is formed on the first axis, the first planar Hall element being arranged to generate a first signal; a second planar Hall element that is formed on the second axis, the second planar Hall element being arranged to generate a second signal; a third planar hall element that is formed on the first axis, the third planar Hall element being arranged to generate a third signal; and a fourth planar Hall element that is formed on the second axis, the fourth planar Hall element being arranged to generate a fourth signal; and a processing circuit configured to: (i) generate a first combined signal based on the difference between the first and third signals and a difference between the second and fourth signals, and (ii) generate second combined signal based on a difference between the first and third signals and a difference between the fourth and second signals.

### BRIEF DESCRIPTION OF THE DRAWINGS

The foregoing features may be more fully understood from the following description of the drawings in which:

FIG. 1A is a top-down view of an example of a system that includes a sensor and a ring magnet, according to aspects of the disclosure;

FIG. 1B is a top-down view of the system of FIG. 1A, according to aspects of the disclosure;

FIG. 1C is a side view of the system of FIG. 1A, according to aspects of the disclosure;

FIG. 1D is a cross-sectional side view of the system of FIG. 1A, according to aspects of the disclosure;

FIG. 2 is a schematic diagram illustrating the operation of the system of FIG. 1A, according to aspects of the disclosure;

FIG. 3A is a top-down view of the sensor that is part of the system of FIG. 1A, according to aspects of the disclosure;

FIG. 3B is a side view of the sensor of FIG. 3A, according to aspects of the disclosure;

FIG. 3C is a side view of the sensor of FIG. 3A, according to aspects of the disclosure;

FIG. 3D is a side view of the sensor of FIG. 3A, according to aspects of the disclosure;

FIG. 3E is a side view of the sensor of FIG. 3A, according to aspects of the disclosure;

FIG. 3F is a top-down view of the sensor of FIG. 3A, according to aspects of the disclosure;

FIG. 3G is a top-down view of the sensor of FIG. 3A with the ring magnet of the system of FIG. 1A, according to aspects of the disclosure;

FIG. 4A is a top-down view of a system including a ring magnet and a sensor, according to aspects of the disclosure;

FIG. 4B is a top-down view of another system including a ring magnet and a sensor, according to aspects of the disclosure;

FIG. 5 is a circuit diagram of the system of FIG. 4A or 4B, according to aspects of the disclosure;

FIG. 6A is a top-down view of the system of FIG. 4A or 4B, according to aspects of the disclosure;

FIG. 6B is a plot illustrating aspects of the operation of the system of FIG. 4A or 4B, according to aspects of the disclosure;

FIG. 6C is a plot illustrating aspects of the operation of the system of FIG. 4A or 4B, according to aspects of the disclosure;

FIG. 6D is a plot illustrating aspects of the operation of the system of FIG. 4A or 4B, according to aspects of the disclosure;

FIG. 6E is a plot illustrating aspects of the operation of the system of FIG. 4A or 4B, according to aspects of the disclosure;

FIG. 7A is top-down view of an example of a system including a magnet and a sensor, according to aspects of the disclosure;

FIG. 7B is side view of an example of a system including a magnet and a sensor, according to aspects of the disclosure;

FIG. 7C is cross-sectional side view of the sensor of the system of FIG. 7A, according to aspects of the disclosure;

FIG. 8 is schematic diagram illustrating the operation of the system of FIG. 7A, according to aspects of the disclosure;

FIG. 9A is a schematic diagram of the system of FIG. 8A, according to aspects of the disclosure;

FIG. 9B is a flowchart of an example of a process, according to aspects of the disclosure; and

FIG. 10 is a plot of signals that are generated by using the sensor 710, according to aspects of the disclosure.

FIG. 11 is a circuit diagram of a system including the sensor of FIG. 7C, according to aspects of the disclosure.

### DETAILED DESCRIPTION

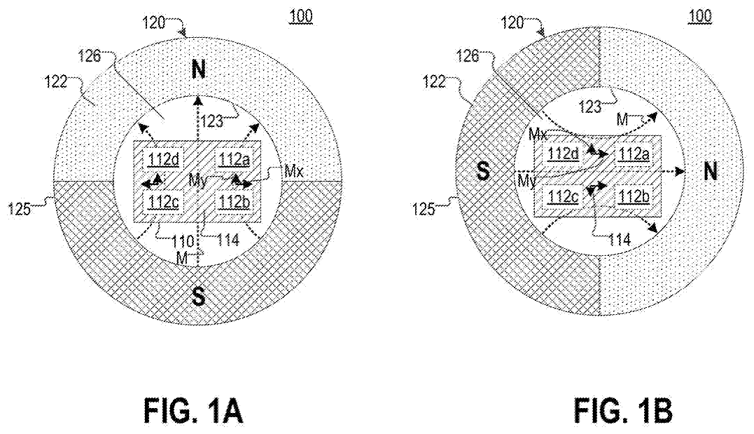

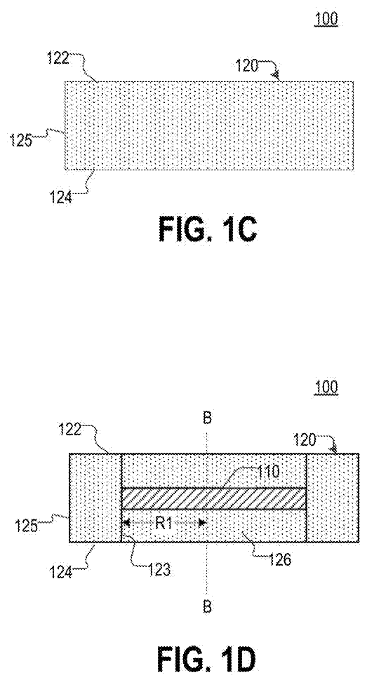

FIGS. 1A-D show an example of a system 100, according to aspects of the disclosure. As illustrated, the system 100 may include a sensor 110 and a ring magnet 120. The ring magnet 120 may include a top surface 122, a bottom surface 124, and a bore 126 that extends from the top surface 122 to the bottom surface 124. The ring magnet 120 may have an inner sidewall 123 (which defines the bore 126) and outer sidewall 125. The ring magnet 120 may also have an inner radius R1, and the bore 126 of the ring magnet 120 may have a longitudinal axis B-B, as shown. The inner sidewall 123 may be symmetrical with respect to the longitudinal axis B-B (i.e., the longitudinal axis B-B can be a central longitudinal axis with the inner sidewall 123 concentric with respect to the central longitudinal axis), and the inner radius R1 may be the distance between the inner sidewall 123 and the longitudinal axis B-B.

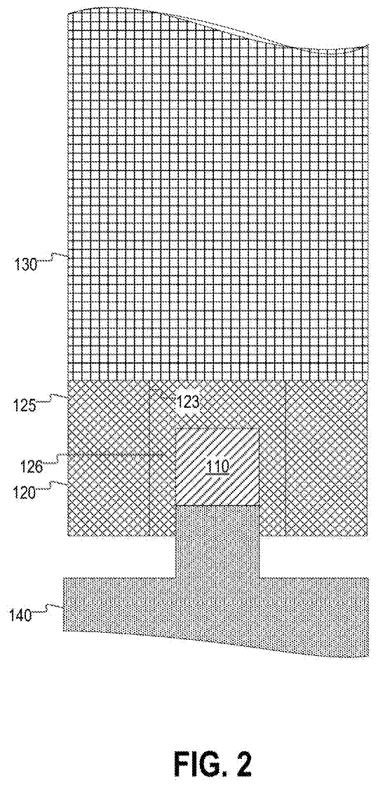

The sensor 110 may be disposed inside the bore 126, and subjected to a magnetic field M (indicated by dashed arrows in FIGS. 1A-B). The sensor 110 may include groups of Hall effect elements 112 and processing circuitry that are formed on a substrate 114. As illustrated in FIG. 2, in operation, the ring magnet 120 may be coupled to a rotating shaft 130, and the sensor 110 may be provided in the form of an integrated circuit (IC) mounted on a mounting member 140. The ring magnet 120 may turn with the rotating shaft 130, while the sensor 110 may remain in a fixed position. As a result of this arrangement, the direction of the magnetic field M may change (as illustrated in FIGS. 1A-B), and this change may be reflected in the signals that are generated by each Hall element group 112. The signals that are generated by each of the Hall elements in Hall element groups 112 may be used to determine the angular position and/or speed of the rotating shaft 130 (and in some embodiments also the direction of rotation). According to the example of FIGS. 1A-E, the longitudinal axis B-B of the bore 126 is coincident with the axis of rotation of the ring magnet 120.

Hall element groups 112 may include magnetic field sensing elements that have an axis of maximum sensitivity parallel to the major, active surface (e.g., top surface 122) of the substrate supporting the elements (e.g., Hall element groups 112 may comprise vertical Hall elements) as explained further below. Consideration of FIGS. 1A and 1B reveals that as the magnet 120 rotates, the magnetic field lines through the elements likewise rotate. The X and Y components of the magnetic field M are labeled Mx and My. Considering elements in groups 112a and 112d as an example, in FIG. 1A, the y-axis component of the magnetic field My is common to both groups 112a, 112d whereas the x-axis component of the magnetic field Mx is differential (i.e., equal strength on both groups 112a, 112d but opposite polarity). When the magnet is rotated ninety degrees as shown in FIG. 1B, the x-axis component of the magnetic field Mx is common to both groups 112a, 112d whereas the y-axis component of the magnetic field My becomes differential. Thus, combining signals from groups 112a, 112d will yield a differential signal that corresponds to the field M that is desired to be detected (i.e., the field generated by the rotating magnet). Stray magnetic fields are uniform across the sensor regardless of rotational position of the ring magnet 120 and refer generally to fields other than the rotating field M generated by the ring magnet. Thus, the stray magnetic field incident on groups 112a and 112d will always be common to both groups and thus will tend to cancel when signals from groups 112a, 112d are combined or subtracted. It will be appreciated that the resulting stray field immunity is cancelled or removed by placing sensing elements that form differentially processed pairs such that the field lines M intended to be detected are incident on the differentially processed pairs of elements in the same direction.

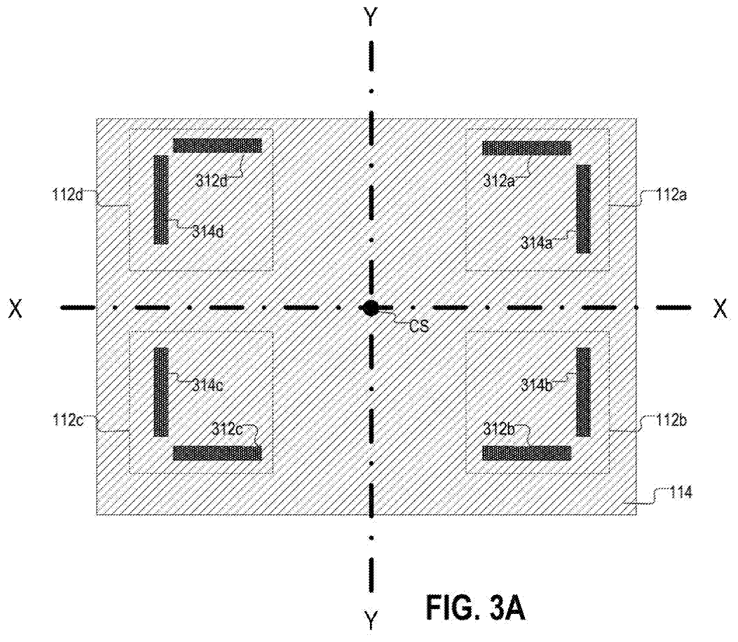

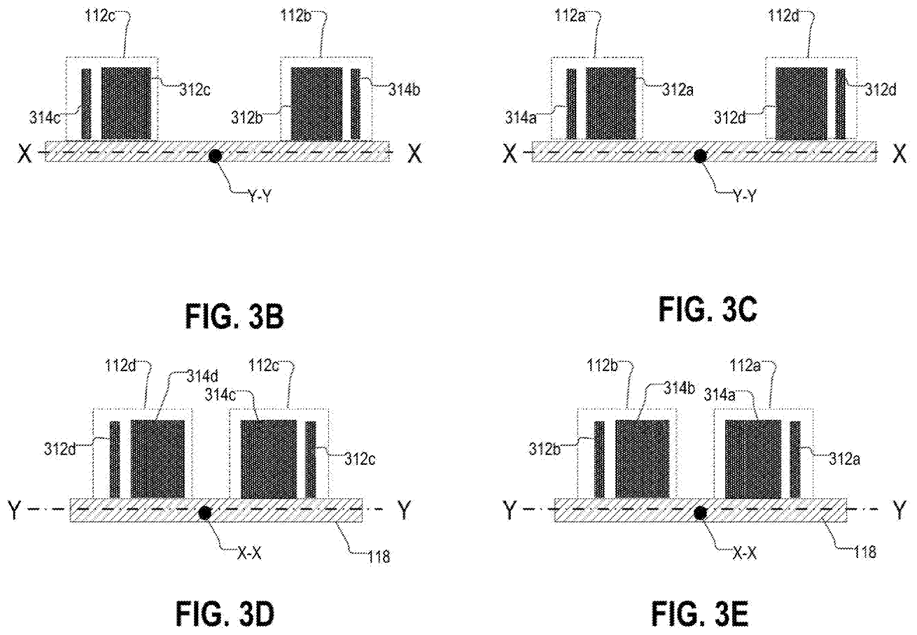

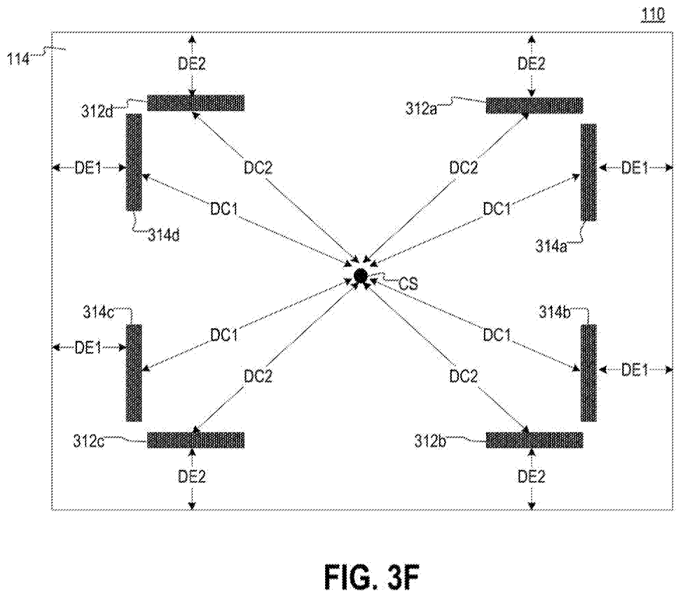

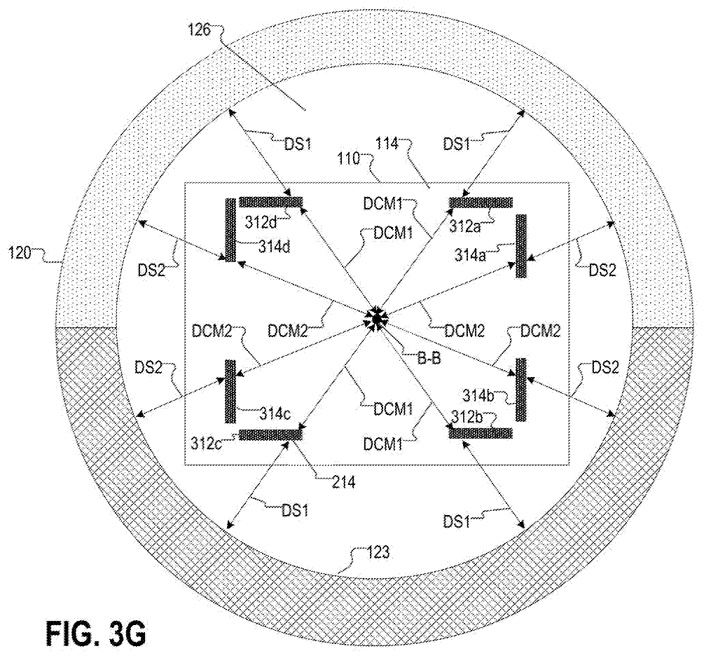

FIGS. 3A-E show the sensor 110 in further detail. As illustrated the sensor 110 may have central axes X-X and Y-Y, which are substantially orthogonal to one another and intersect at the center CS of the substrate 114. Each of the Hall element groups 112 may include a respective vertical Hall element 312 and a respective vertical Hall element 314. Specifically, Hall element group 112a may include a vertical Hall element 312a and a vertical Hall element 314a; Hall element group 112b may include a vertical Hall element 312b and a vertical Hall element 314b; Hall element group 112c may include a vertical Hall element 312c and a vertical Hall element 314c; and Hall element group 112d may include a vertical Hall element 312d and a vertical Hall element 314d.

Vertical Hall elements are constructed from top to bottom along the depth of the substrate 114 and can be oriented to sense X, Y, or other directions parallel to a major, active surface 118 of the substrate 114 (i.e., semiconductor die) in which they are formed. Stated differently, vertical Hall elements have an axis of maximum sensitivity parallel to the major surface 118 of the substrate 114 that supports the element (in-plane fields). It will be appreciated that the side views of FIGS. 3B-E show the vertical Hall elements with an exaggerated depth for illustration purposes and that such elements generally do not extend above the major surface of the substrate. Each of the vertical Hall elements 312 may be aligned with the axis X-X, and each of the vertical Hall elements 314 may be aligned with the axis Y-Y. Accordingly, any two vertical Hall elements 312 and 314 that are part of the same Hall element group 112 may be orthogonal (i.e., arranged at a 90-degree angle) relative to one another. For example, the axes of maximum sensitivity of vertical Hall elements 312a and 314a may be at a 90-degree angle relative to one another; the axes of maximum sensitivity of vertical Hall elements 312b and 314b may be at a 90-degree angle relative to one another; the axes of maximum sensitivity of vertical Hall elements 312c and 314c may be at a 90-degree angle relative to one another; and the axes of maximum sensitivity of vertical Hall elements 312d and 314d may be at a 90-degree angle relative to one another. This arrangement allows the signals output from the vertical Hall elements in any of the Hall element groups 112 to be in quadrature with one another, which in turn allows the signals to be easily used for determining the angular position of the ring magnet 120 (and/or shaft 130) relative to the sensor 110.

In the example of FIGS. 3A-G each group 112 includes vertical Hall elements whose axes of maximum sensitivity are arranged at an angle relative to one another (e.g., 90 degrees). However, alternative implementations are possible in which each of the groups 112 is implemented by using any other suitable type of magnetic transducers whose axes of maximum sensitivity are at an angle relative to one another and substantially parallel to the main surface of the substrate. Such magnetic field sensing elements may include vertical Hall elements, giant magnetoresistors (GMR), tunnel magnetoresistors (TMR), and or any other suitable type of magnetic transducer having an axis of maximum sensitivity that is substantially parallel with the plane of the substrate on which the magnetic transducer is formed, etc.

As used throughout the disclosure, the phrase “magnetic field sensing element is aligned with a given axis” shall be interpreted as “a magnetic field sensing element whose axis of maximum sensitivity is aligned (e.g., substantially parallel) with the given axis”. FIG. 3F shows in further detail the relative positioning of each of the vertical Hall elements 312 and 314 with respect to the substrate 114. As illustrated in FIG. 3F, the vertical Hall elements 312 may be disposed on the periphery of the substrate 114. Each of the vertical Hall elements 312 may be disposed at a distance DE2 from the nearest edge of the substrate 114, and each of the vertical Hall elements 312 may be disposed at a distance DC2 from the center CS of the substrate 114, where DE2<DC2. In some implementations, the distance DE2 may be at least 90% smaller than the distance DC2. Additionally or alternatively, in some implementations, each of the vertical Hall elements 312 may be disposed at the very edge of the substrate 114, in which case the distance DE2 may be very close to zero. For instance, the vertical Hall elements 312 may be formed as close to the edge(s) of the substrate 114 as the manufacturing process used permits. Each of the vertical Hall elements 314 may be disposed at a distance DE1 from the nearest edge of the substrate 114, and each of the vertical Hall elements 314 may be disposed at a distance DC1 from the center CS of the substrate 114, where DE1<DC1. In some implementations, the distance DE1 may be at least 90% smaller than the distance DC1. Additionally or alternatively, in some implementations, each of the vertical Hall elements 312 and 314 may be disposed at the very edge of the substrate 114, in which case the distance DC1 may be close to zero. For instance, the vertical Hall elements 314 may be formed as close to the edge(s) of the substrate 114 as the manufacturing process used permits. In some respects, disposing the vertical Hall elements 312 and 314 on the periphery of the substrate 114 is advantageous because it may result in an higher amount of magnetic flux being incident on the vertical Hall elements 312 and 314 than if the elements were closer to the center of the substrate, which in turn could increase the sensitivity of the sensor 110 with respect to the position of the ring magnet 120.

According to the present example, the distance DE1 is equal to the distance DE2. However, alternative implementations are possible in which the distance DE1 is different from the distance DE2. According to the present example, the distance DC1 is equal to the distance DC2. However, alternative implementations are possible in which the distance DC1 is different from the distance DC2.

Although in the example of FIG. 3F each of the vertical Hall elements 312 is spaced by the same distance from the edge of the substrate that is nearest to the vertical Hall element 312, alternative implementations are possible in which any two of the vertical Hall elements 312 are spaced by different distances from the respective edges of the substrate 114 that are closest to the two vertical Hall elements. Although in the example of FIG. 3F each of the vertical Hall elements 314 is spaced by the same distance from the edge of the substrate that is nearest to the vertical Hall element 314, alternative implementations are possible in which any two of the vertical Hall elements 314 are spaced by different distances from the respective edges of the substrate 114 that are closest to the two vertical Hall elements.

FIG. 3G shows in further detail the relative positioning of each of the vertical Hall elements 312 and 314 with respect to the ring magnet 120 when the sensor 110 is installed in the bore 126 of the ring magnet 126. As illustrated, each vertical Hall element 312 may be positioned at a distance DCM1 from the longitudinal axis B-B of the bore 126 of the ring magnet 120 and each vertical Hall element 314 may be positioned at a distance DCM2 from the longitudinal axis B-B of the bore 126 of the ring magnet 120. Furthermore, each of the vertical Hall elements 312 may be positioned at a distance DS1 from the inner sidewall 123 of the ring magnet 120, and each of the vertical Hall elements 314 may be positioned at a distance DS2 from the inner sidewall 123 of the ring magnet 120.

According to the present example, the distance DS1 is equal to the distance DS2. However, alternative implementations are possible in which the distance DS1 is different from the distance DS2. According to the present example, the distance DCM1 is equal to the distance DCM2. However, alternative implementations are possible in which the distance DCM1 is different from the distance DCM2. Although in the example of FIG. 3G each of the vertical Hall elements 312 is spaced by the same distance from the inner sidewall 123 of the ring magnet 120, alternative implementations are possible in which any two of the vertical Hall elements 312 are spaced by a different distance from the inner sidewall 123 of the ring magnet 120. Although in the example of FIG. 3G each of the vertical Hall elements 312 is spaced by the same distance from the longitudinal axis B-B of the bore 126 of the ring magnet 120, alternative implementations are possible in which any two of the vertical Hall elements 312 are spaced by a different distance from the longitudinal axis B-B of the bore 126 of the ring magnet 120. Although in the example of FIG. 3G each of the vertical Hall elements 314 is spaced by the same distance from the inner sidewall 123 of the ring magnet 120, alternative implementations are possible in which any two of the vertical Hall elements 314 are spaced by a different distance from the inner sidewall 123 of the ring magnet 120. Although in the example of FIG. 3G each of the vertical Hall elements 314 is spaced by the same distance from the longitudinal axis B-B of the bore 126 of the ring magnet 120, alternative implementations are possible in which any two of the vertical Hall elements 314 are spaced by a different distance from the longitudinal axis B-B of the bore 126 of the ring magnet 120.

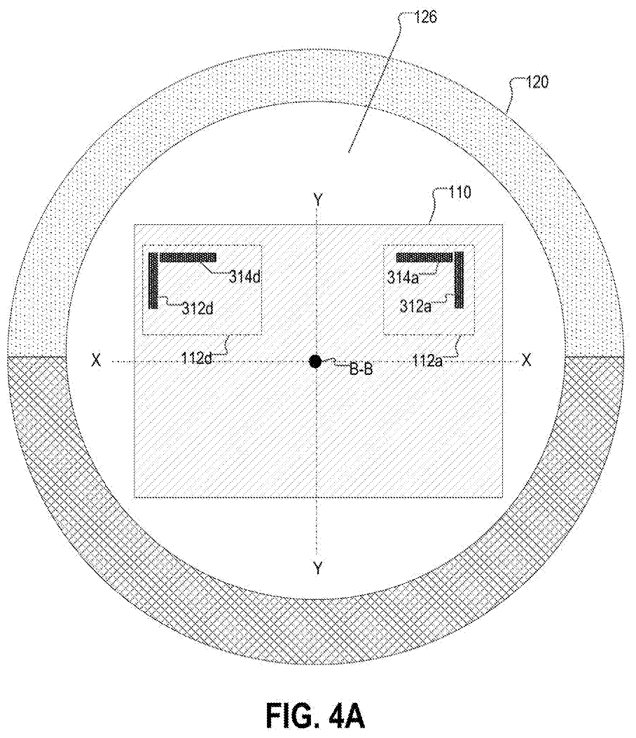

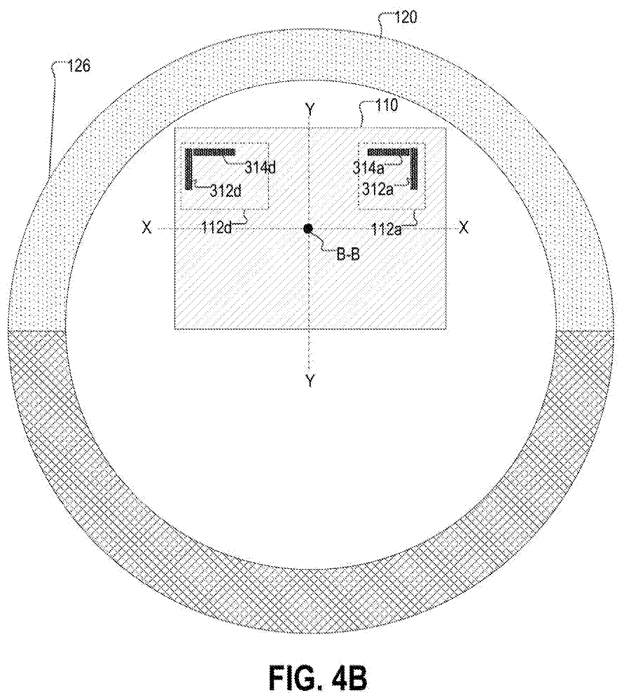

FIG. 4A shows the sensor 110 in accordance with another implementation. In this implementation, the sensor 110 includes only Hall element groups 112a and 112d. As illustrated, in implementations in which the sensor 110 includes only two groups of vertical Hall elements, both groups of vertical Hall elements may be disposed on the substrate 114 in an arrangement that is asymmetrical with respect to the longitudinal axis B-B of the bore 126 of the ring magnet 120. Hall element groups 112a and 112d are also in an arrangement that is asymmetrical with respect to axis X-X, but symmetrical with respect to axis Y-Y, as shown. Specifically, both groups of vertical Hall elements may be disposed adjacent to the same edge 110a of the substrate 114 (rather than being diagonally-opposed). With this configuration, rotation of the ring magnet 120 will result in incident magnetic field line variations of the same general type described above in connection with FIGS. 1A-B, thereby achieving stray field immunity. Although there can be a cost and space advantage to using only the two groups of vertical Hall elements as shown in FIG. 4A, using all four groups 112a, 112b, 112c, 112d (FIG. 1) can provide a more symmetrical configuration

According to aspects of the disclosure, positioning both pairs of sensing elements on the same side of the bore 126, as shown—in FIG. 4A, is advantageous because it allows the sensor 110 to get fully differential signals from elements 312a-312d and 314a-314d respectively. If these two pairs were placed in diagonally opposed directions then no differential signals could be generated in any of the two pairs, and therefore stray field cancellation would not be possible. As can be readily appreciated, both pairs sensing elements can be on one side of the substrate as shown in FIG. 4A, above or both below the X-X axis, or alternatively both sensing element pairs can be positioned on the left or right of the Y-Y axis.

In some respects, having four Hall element groups 112 in the sensor 110 is advantageous because it may provide another degree of symmetry and help increase immunity to second order effects, like mechanical stresses or on-die thermal gradients. Having, two groups 112 of vertical Hall element groups 112 however is advantageous because it could help decrease the size and/or cost of manufacturing the sensor 110, while maintaining more than adequate immunity to second order effects.

The four groups are better to increase immunity to second order effects like: mechanical stresses or on-die thermal gradients: having two pairs may only partially cancel those gradients, while having four pairs provides another degree of symmetry and therefore should cancel most gradients.

In the embodiment of FIG. 4A, similar to the embodiment of FIG. 3A, the vertical Hall elements are positioned at or near the periphery of the substrate to achieve a higher level of incident magnetic flux achieved by having the elements proximate to the magnet. It will be appreciated that the effect of increased magnetic flux achieved by positioning the elements near or along the periphery of the substrate (i.e., rather than nearer to the center of the substrate) can be enhanced by reducing the inner diameter of the ring magnet, both achieving the result of positioning the transducers closer to the magnet. Another way to achieve this increased magnetic flux incident on the sensing elements is by displacing the substrate with respect to the longitudinal bore of the magnet as shown in FIG. 4B.

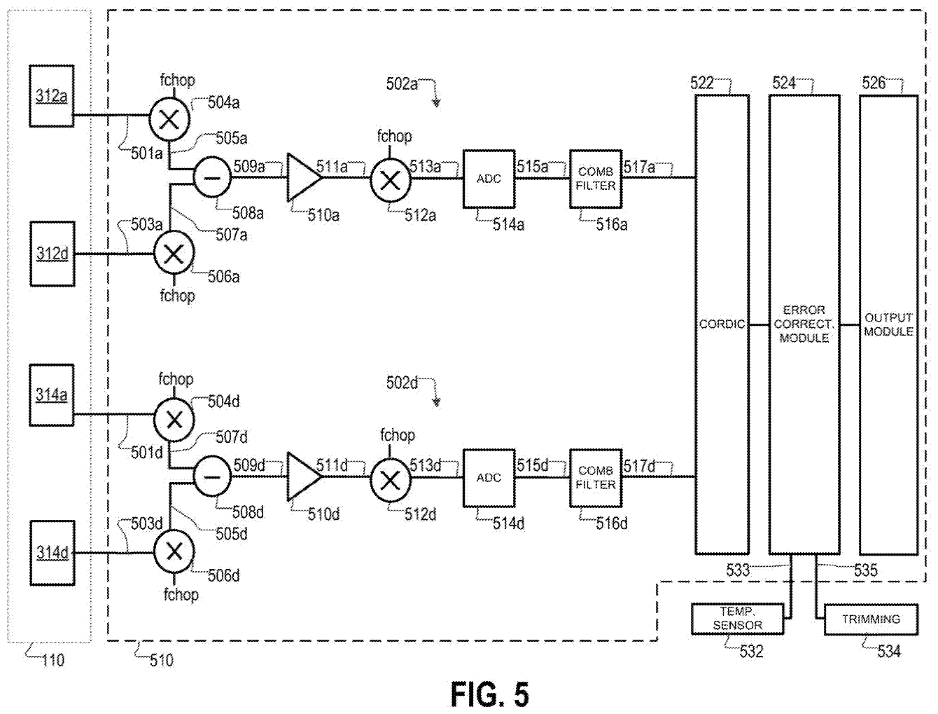

FIG. 5 is a circuit diagram of a processing circuitry 510 that is used in conjunction with the implementation of the sensor 110 which is shown in FIG. 4A or 4B. The processing circuitry 510 may include a processing path 502a and a processing path 502d. The processing path 502a may be arranged to process signals that are generated by the vertical Hall elements 312a and 312d and the processing path 502d may be arranged to process signals that are generated by the vertical Hall elements 314a and 314d.

The vertical Hall element 312a may generate a signal 501a that is subsequently provided to a modulator 504a. The modulator 504a may modulate the signal 501a based on a frequency fchop to produce a modulated signal 505a. The vertical Hall element 312d may generate a signal 503a that is subsequently provided to a modulator 506a. The modulator 506a may modulate the signal 503a based on the frequency fchop to produce modulated signal 507a. A subtractor 508a may subtract the modulated signal 507a from the modulated signal 505a to produce a differential signal 509a, which is subsequently provided to an amplifier 510a. As can be readily appreciated from the discussion above, subtracting the two signals from one another may cancel out the effects of stray magnetic fields that are incident on the vertical Hall elements 312a and 312d, resulting in signal 509a being immune to stray field effects. The amplifier 510a may amplify the signal 509a to produce an amplified signal 511a, which is subsequently provided to a demodulator 512a. The demodulator 512a may demodulate the amplified signal 511a based on the frequency fchop to produce a demodulated signal 513a, which is subsequently provided to an analog-to-digital converter (ADC) 514a. The ADC 514a may digitize the demodulated signal 513a to produce a digital signal 515a, which is subsequently provided to a filter 516a, as may be a comb filter in embodiments. The filter 516a may filter the digital signal 515a to produce a filtered signal 517a, which is subsequently provided to a CORDIC module 522.

The vertical Hall element 314a may generate a signal 501d that is subsequently provided to a modulator 504a. The modulator 504d may modulate the signal 501d based on a frequency fchop to produce a modulated signal 505a. The vertical Hall element 314d may generate a signal 503d that is subsequently provided to a modulator 506a. The modulator 506d may modulate the signal 503d based on the frequency fchop to produce modulated signal 507a. A subtractor 508d may subtract the modulated signal 507d from the modulated signal 505d to produce a signal 509d, which is subsequently provided to an amplifier 510a. As can be readily appreciated from the discussion above, subtracting the two signals from one another may cancel out the effects of stray magnetic fields that are incident on the vertical Hall elements 314a and 314d, resulting ins signal 509d being immune to stray field effects. The amplifier 510d may amplify the signal 509d to produce an amplified signal 511a, which is subsequently provided to a demodulator 512a. The demodulator 512d may demodulate the amplified signal 511d based on the frequency fchop to produce a demodulated signal 513a, which is subsequently provided to an analog-to-digital converter (ADC) 514a. The ADC 514d may digitize the demodulated signal 513d to produce a digital signal 515a, which is subsequently provided to a comb filter 516a. The comb filter 516d may filter the digital signal 515d to produce a filtered signal 517a, which is subsequently provided to a CORDIC module 522.

The CORDIC module 522 may include any suitable type of processing circuitry that is configured to execute a Coordinate Rotation Digital Computer (CORDIC) algorithm or otherwise compute an arctangent function (e.g., such as by using a look-up table). According to the example of FIG. 5, the CORDIC module is configured to calculate a raw position signal based on the filtered signal 517a and the filtered signal 517d. The raw position signal may identify the orientation of the ring magnet 120 relative to the sensor 110, and it may be indicative of angular displacement and/or rotational speed of the ring magnet 120 (and/or the rotating shaft 130). In some implementations, the raw position signal may be calculated in accordance with Equation 1 below:

$${S}_{raw} = arctan ( \frac{{signal}_{517 a}}{{signal}_{517 d}} ) \qquad ( Eq . 1 )$$

where S_{raw} is the raw position signal, signal₅₁₇ₐ is signal 517a, and signal_{571d} is signal 517d.

The error correction module 524 may include any suitable type of processing circuitry for adjusting the gain and/or offset of the raw position signal that is produced by the CORDIC module 522. In operation, the error correction module 524 may receive the raw position signal from the CORDIC module 522 and generate an adjusted signal based on the received raw position signal. The adjusted signal may be generated by adjusting the gain and/or offset of the raw position signal. The gain and/or offset of the raw position signal may be adjusted, in a well-known fashion, based on a signal 533 that is generated by a temperature sensor 532. Additionally or alternatively, the gain and/or offset of the raw position signal may be adjusted based on a signal 535 that is generated by a trim module 534. The trim module 534 may be a memory that is arranged to provide (to the error correction module) one or more coefficients for adjusting the gain and/or offset of the raw position signal. However, alternative implementations are possible in which the trim module 534 includes another type of device (e.g., a humidity sensor, etc.) that is used for correcting the gain and/or offset of the raw position signal. Stated succinctly, the present disclosure is not limited to any specific method for adjusting the gain and/or offset of the raw position signal.

The output module 526 may include any suitable type of communications interface for outputting the adjusted signal that is produced by the error correction module 524. The output block may format the adjusted signal into a desired output signal format and provide the formatted signal to another device (e.g. an Engine Control Unit) that is coupled to the output module 526. The desired format may be PWM format, Single Edge Nibble Transmission (SENT) format, a Serial Peripheral Interface (SPI) format, a Local Interconnect Network (LIN) format, a CAN (Controller Area Network) format, an Inter-Integrated Circuit (I²C) format to name a few non-limiting examples.

FIG. 5 is provided in the context of the implementation of the sensor 110 that is shown in FIG. 4B, in which the sensor 110 is provided with two pairs of sensing elements. In the example of FIG. 5, the signal S_{raw} is generated by taking the arctan of the quotient of signals 517a and 517d, where signals 517a and 517d are generated in accordance with equations 2 and 3 below:

signal₅₁₇ₐ=signal₃₁₂ₐ−signal_{312d} (2)

signal_{517d}=signal₃₁₄ₐ−signal_{314d} (3)

where signal₃₁₂ₐ is the signal output from sensing element 312a (also referred to as signal 501a in FIG. 5), signal_{312d} is the signal output from sensing element 312d (also referred to as signal 503a in FIG. 5), signal₃₁₄ₐ is the signal output from sensing element 314a (also referred to as signal 501d in FIG. 5), and signal_{314d} is the signal output from sensing element 314d (also referred to as signal 503d in FIG. 5).

In the implementation shown in FIG. 3G, in which the sensor 110 is provided with four pairs of sensing elements, the signals 517a and 517d may be generated in accordance with equations 4 and 5 below:

signal₅₁₇ₐ=(signal₃₁₂ₐ+signal_{312c})−(signal_{312d}+signal_{312b}) (4)

signal_{517d}=(signal₃₁₄ₐ+signal_{314c})−(signal_{314d}+signal_{314b}) (5)

where signal₃₁₂ₐ is the signal output from sensing element 312a, signal_{312b} is the signal output from sensing element 312b, signal_{312c} is the signal output from sensing element 312c, signal_{312d} is the signal output from sensing element 312d, signal₃₁₄ₐ is the signal output from sensing element 314a, signal_{314b} is the signal output from sensing element 314b, signal_{314c} is the signal output from sensing element 314c, signal_{314d} is the signal output from sensing element 314d. The signals 517a and 517d, which are generated in accordance with equations 4 and 5, may be used to generate a signal Sraw, as discussed above with respect to Equation 1. As can be readily appreciated, equations 2-5 are provided for illustrative purposes only, and they do not reflect demodulation, amplification, filtering, and/or any other signal processing that might take place.

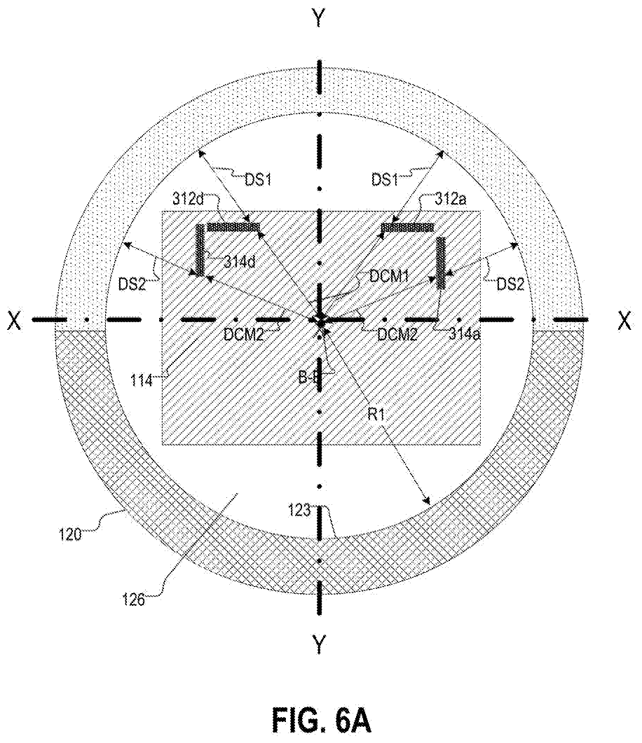

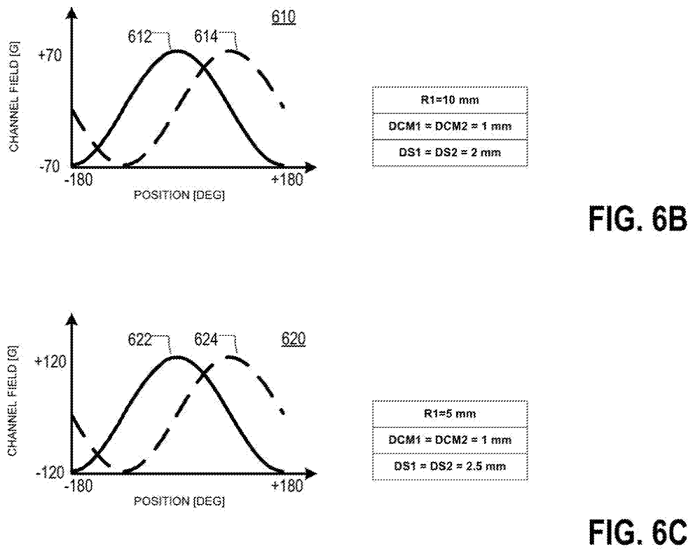

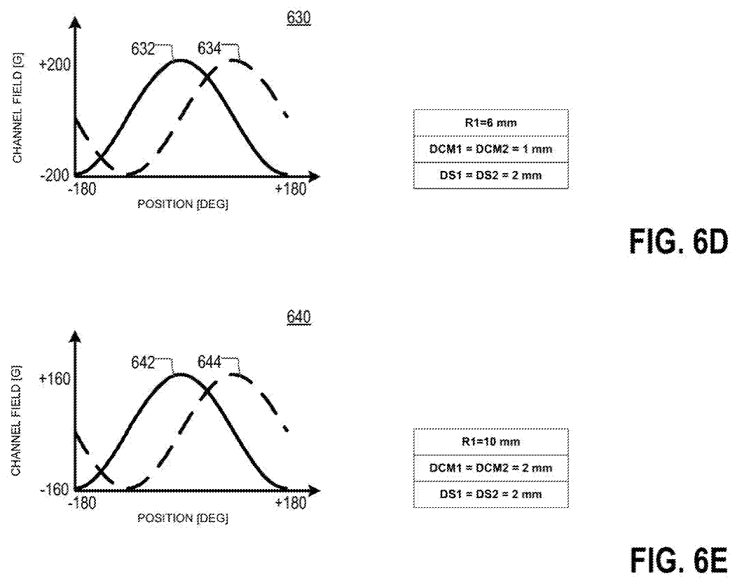

FIG. 6A illustrates in further detail the impact of three parameters of the sensor 110 on the operation of the sensor 110. The parameters include: (i) the inner radius R1 of the ring magnet, the distance DCM1 between each of the vertical Hall elements 312a and 312d and the longitudinal axis B-B of the bore 126 of the ring magnet 120, (ii) the distance DCM2, between each of the vertical Hall elements 314a and 314d and the longitudinal axis B-B of the bore 126 of the ring magnet 120, (iii) the distance DS1 between each of the vertical Hall elements 312a and 312d and the inner sidewall 123 of the ring magnet 120, and (iv) the distance DS2 between each of the vertical Hall elements 314a and 314d and the inner sidewall 123 of the ring magnet 120.

FIG. 6B is a plot 610 of curves 612 and 614. Curve 612 represents the magnetic field strength that would be sensed by the sensor 110 along axis X-X (i.e., represents the magnetic field signal sensed by x-axis oriented element 314a or 314d) when R1 is set to 10 mm, DCM1 and DCM2 are both set to 1 mm, and DS1 and DS2 are both set to 2 mm. Curve 614 represents the magnetic field strength that would be sensed by the sensor 110 along axis Y-Y (i.e., represents the magnetic field signal sensed by y-axis oriented element 312a or 312d) when R1 is set to 10 mm, DCM1 and DCM2 are both set to 1 mm, and DS1 and DS2 are both set to 2 mm. Together, curves 612 and 614 illustrate that the measured strength of magnetic field M would vary between +70G and −70G when R1 is set to 10 mm, DCM1 and DCM2 are both set to 1 mm, and DS1 and DS2 are both set to 2 mm.

FIG. 6C is a plot 620 of curves 622 and 624. Curve 622 represents the magnetic field strength that would be sensed by the sensor 110 along axis X-X (i.e., represents the magnetic field signal sensed by x-axis oriented element 314a or 314d) when R1 is set to 10 mm, DCM1 and DCM2 are both set to 1 mm, and DS1 and DS2 are both set to 2.5 mm. Curve 624 represents the magnetic field strength that would be sensed by the sensor 110 along axis Y-Y (i.e., represents the magnetic field signal sensed by y-axis oriented element 312a or 312d) when R1 is set to 10 mm, DCM1 and DCM2 are both set to 1 mm, and DS1 and DS2 are both set to 2.5 mm. Together, curves 622 and 624 illustrate that the measured strength of magnetic field M would vary between +120G and −120G when R1 is set to 10 mm, DCM1 and DCM2 are both set to 1 mm, and DS1 and DS2 are both set to 2.5 mm.

FIG. 6D is a plot 630 of curves 632 and 634. Curve 632 represents the magnetic field strength that would be sensed by the sensor 110 along axis X-X (i.e., represents the magnetic field signal sensed by x-axis oriented element 314a or 314d) when R1 is set to 6 mm, DCM1 and DCM2 are both set to 1 mm, and DS1 and DS2 are both set to 2 mm. Curve 634 represents the magnetic field strength that would be sensed by the sensor 110 along axis Y-Y (i.e., represents the magnetic field signal sensed by y-axis oriented element 312a or 312d) when R1 is set to 6 mm, DCM1 and DCM2 are both set to 1 mm, and DS1 and DS2 are both set to 2 mm. Together, curves 632 and 634 illustrate that the measured strength of magnetic field M would vary between +200G and −200G when R1 is set to 6 mm, DCM1 and DCM2 are both set to 1 mm, and DS1 and DS2 are both set to 2 mm.

FIG. 6E is a plot 640 of curves 642 and 644. Curve 642 represents the magnetic field strength that would be sensed by the sensor 110 along axis X-X (i.e., represents the magnetic field signal sensed by x-axis oriented element 314a or 314d) when R1 is set to 5 mm, DCM1 and DCM2 are both set to 1 mm, and DS1 and DS2 are both set to 2 mm. Curve 644 represents the magnetic field strength that would be sensed by the sensor 110 along axis Y-Y (i.e., represents the magnetic field signal sensed by y-axis oriented element 312a or 312d when R1 is set to 5 mm, DCM1 and DCM2 are both set to 2 mm, and DS1 and DS2 are both set to 2 mm. Together, curves 642 and 644 illustrate that the measured strength of magnetic field M would vary between +160G and −160G when R1 is set to 10 mm, DCM1 and DCM2 are both set to 2 mm, and DS1 and DS2 are both set to 2 mm.

In some respects, FIGS. 6B-E illustrate that the closer the elements are symmetrically in place to the inner sidewall 123 of the ring magnet 120, the larger the magnetic field strength that would be incident on the sensor 110. According to the present disclosure, it has been found that the distance between the inner sidewall 123 of the ring magnet 120 and any of the vertical Hall elements 312a, 312d, 314a, and 314d of at most 2 mm is desirable in order to obtain acceptable magnetic field levels. Furthermore, FIGS. 6B-E further illustrate that reducing the inner radius R1 of the ring magnet 120 may have a similar effect to increasing the magnetic flux density that is incident on the sensor 110.

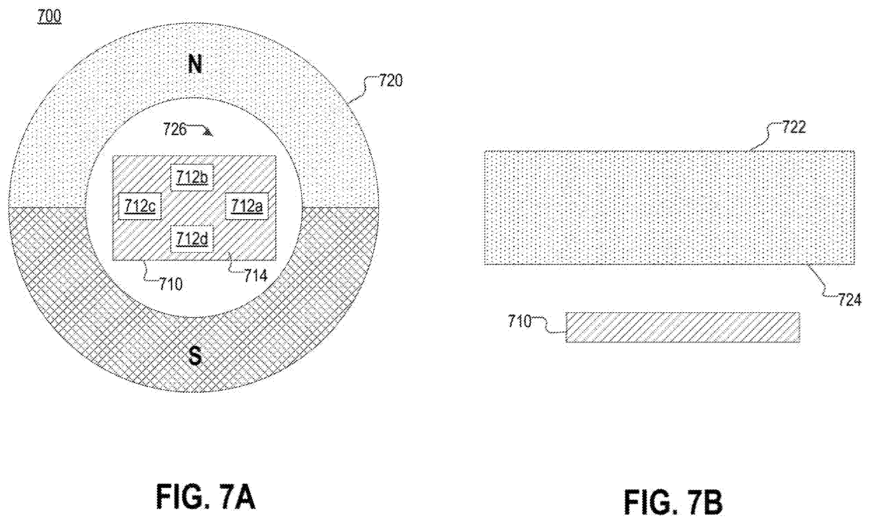

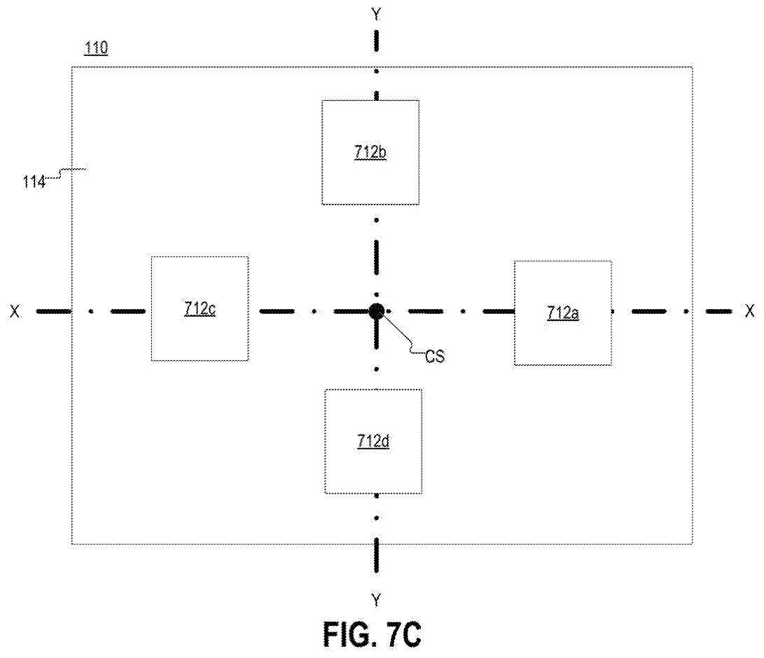

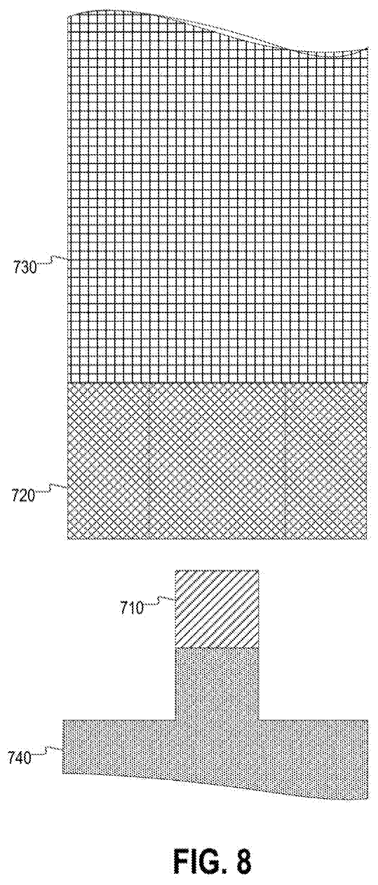

FIGS. 7A-D show an example of a system 700, according to aspects of the disclosure. As illustrated, the system 700 may include a sensor 710 and a ring magnet 720. The ring magnet 720 may include a top surface 722, a bottom surface 724, and a bore 726 that extends from the top surface 722 to the bottom surface 724. The sensor 710 may be disposed adjacent to the bottom surface 724 of the ring magnet 720 directly above the bore 726 of the ring magnet 120. In other implementations, the sensor 710 may be disposed adjacent to the top surface of the ring magnet 720 directly below the bore 726 of the ring magnet 120. In implementations in which the sensor 710 is off-center from the ring magnet 120, additional circuitry may be used to compensate for harmonic distortion resulting from the off-center positioning of the sensor 710. The sensor 710 may include planar Hall elements 712 that are formed on a substrate 714. The substrate 714 may include an axis X-X and an axis Y-Y. The axes X-X and Y-Y are orthogonal with each other, and they may intersect at the center CS of the substrate 714. The planar Hall elements 712a and 712c may be centered on the axis X-X. And the planar Hall elements 712b and 712d may be centered on the axis Y-Y. It will be appreciated that planar Hall elements have an axis of maximum sensitivity orthogonal to the major, active surface (e.g., top surface 722) of the substrate.

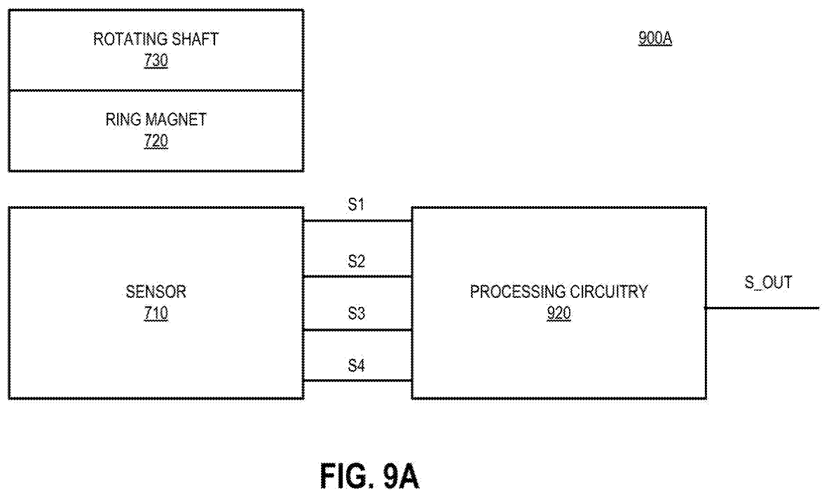

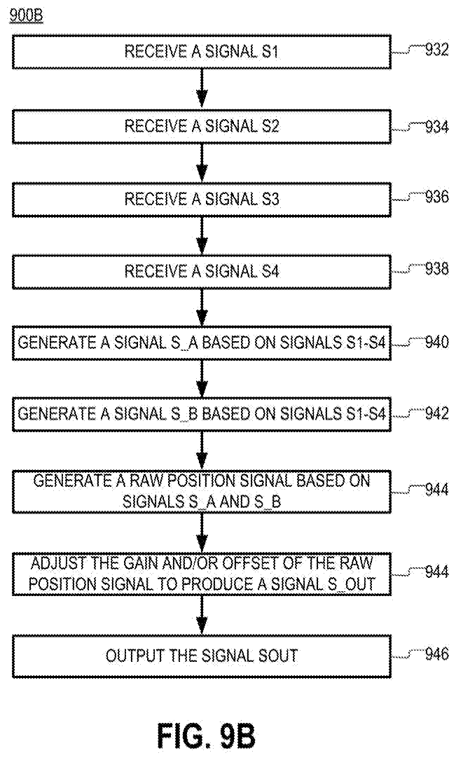

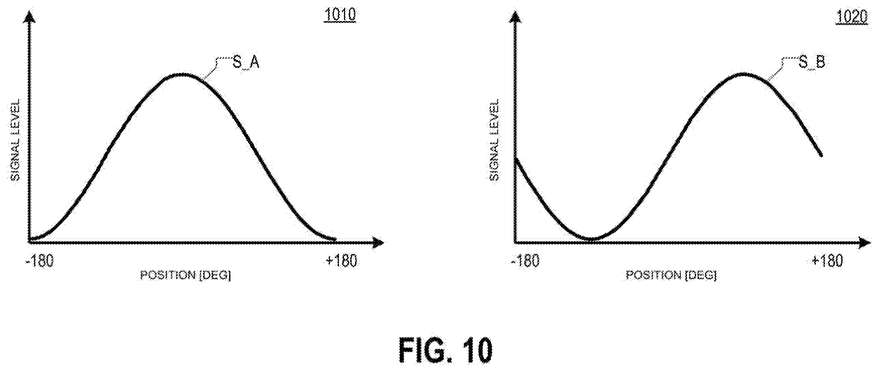

As illustrated in FIG. 7D, the magnet 720 may be coupled to rotating shaft 730 and the sensor 710 may be mounted on a mounting member 740. The ring magnet 720 may turn with the rotating shaft 730, while the sensor 710 may remain fixed in position. As a result of this arrangement, the direction of the magnetic field that is generated by the ring magnet 720 may change, resulting in changes in the signals that are generated by each Hall element group 712. As is discussed further below with respect to FIGS. 9A-10, the signals that are generated by each of the Hall element groups 712 may be used to determine the angular position and/or speed of the rotating shaft 130 (and in some embodiments also the direction of rotation). Although in the example of FIG. 7A-D the sensor 710 is positioned below the ring magnet 120, alternative implementations are possible in which the sensor 710 is positioned above the ring magnet 120. Although in the example of FIGS. 7A-D the magnet 720 is a ring magnet, alternative implementations are possible in which the magnet 720 is a disk, or puck magnet and/or any other suitable type of magnet.

In some respects, arranging the planar Hall elements 712 in this manner is advantageous because it allows the calculation of the angular position (and/or speed) of the ring magnet 720 to be simplified. A simplified approach for calculating the angular position of the ring magnet 720 based on signals generated by the planar Hall elements 712 is discussed further below with respect to FIGS. 9A-B and 11.

FIG. 9A shows an example of a system 900A, according to aspects of the disclosure. The system 900A may include the rotating shaft 730, the ring magnet 720, and the sensor 710, and a processing circuitry 920 that is operatively coupled to the sensor 710. The processing circuitry may be configured to receive signal S1, S2, and S3, and S4 and generate a signal S_OUT based on the signals S1, S2, S3, and S4, respectively. The signal S1 may be generated by the planar Hall element 712a; the signal S2 may be generated by the planar Hall element 812b; the signal S3 may be generated by the planar Hall element 712c; and the signal S4 may be generated by the planar Hall element 712d. The signal S_OUT may indicate the position and/or speed of rotation of the ring magnet 720 (and/or rotating shaft 730). The manner in which the signal S_OUT is generated is discussed further below with respect to FIG. 9B.

FIG. 9B is a flowchart of an example of a process 900B for generating the signal S_OUT. According to the example of FIG. 9B, the process 900B is performed by the processing circuitry 920. However, alternative implementations are possible in which the process 900B is performed by another device. Stated succinctly, the present disclosure is not limited to any specific implementation of the process 900.

At step 932, the processing circuitry 920 receives the signal S1 from the sensor 710. As noted above, the signal S1 is generated by the planar Hall element 712a.

At step 934, the processing circuitry 920 receives the signal S2 from the sensor 710. As noted above, the signal S2 is generated by the planar Hall element 712b.

At step 936, the processing circuitry 920 receives the signal S3 from the sensor 710. As noted above, the signal S3 is generated by the planar Hall element 712c.

At step 938, the processing circuitry 920 receives the signal S4 from the sensor 710. As noted above, the signal S4 is generated by the planar Hall element 712d.

At step 940, a signal S_A is generated based on signals S1-S4. In some implementations, the signal S_A may be generated in accordance with equation 6 below:

S_A=S1+S2−S3−S4 (Eq. 6)

At step 940, the processing circuitry 920 generates a signal S_B based on signals S1-S4. In some implementations, the signal S_B may be generated in accordance with equation 7 below:

S_B=S1−S2−S3+S4 (Eq. 7)

At step 942, the processing circuitry 920 generates a raw position signal based on the signals S_A and S_B. The raw position signal may indicate the angular position and/or speed of rotation of the ring magnet 120 (and/or rotating shaft 730). In some implementations, the raw position signal be generated in accordance with equation 8 below:

$${S}_{raw} = arctan ( \frac{S\_A}{S\_B} ) \qquad ( Eq . 8 )$$

where S_{raw} is the raw position signal.

At step 944, the processing circuitry 920 generates a signal S_OUT by adjusting the gain and/or offset of the raw position signal. The gain and offset may be adjusted in a well-known fashion based on a signal that is provided by a temperature sensor and/or other data. Although in the example of FIG. 9B gain and offset adjustment is performed on the raw position signal, alternative implementations are possible in which gain and/or offset adjustment is performed on any of the signals S1-S4 instead. In this regard, it will be understood that the present disclosure is not limited to any specific method for performing gain and/or offset adjustment.

At step 946, the processing circuitry 920 outputs the signal S_OUT to another device (not shown) that is operatively coupled to the processing circuitry 920.

FIG. 10 shows a plot 1010 of the signal S_A and a plot 1020 of the signal S_B. As illustrated, in some implementations, the signal S_A may have a substantially sinusoidal waveform, and the signal S_B may have a substantially cosinusoidal waveform. According to the example of FIGS. 9A-10, the signals S_A and S_B are in quadrature with one another.

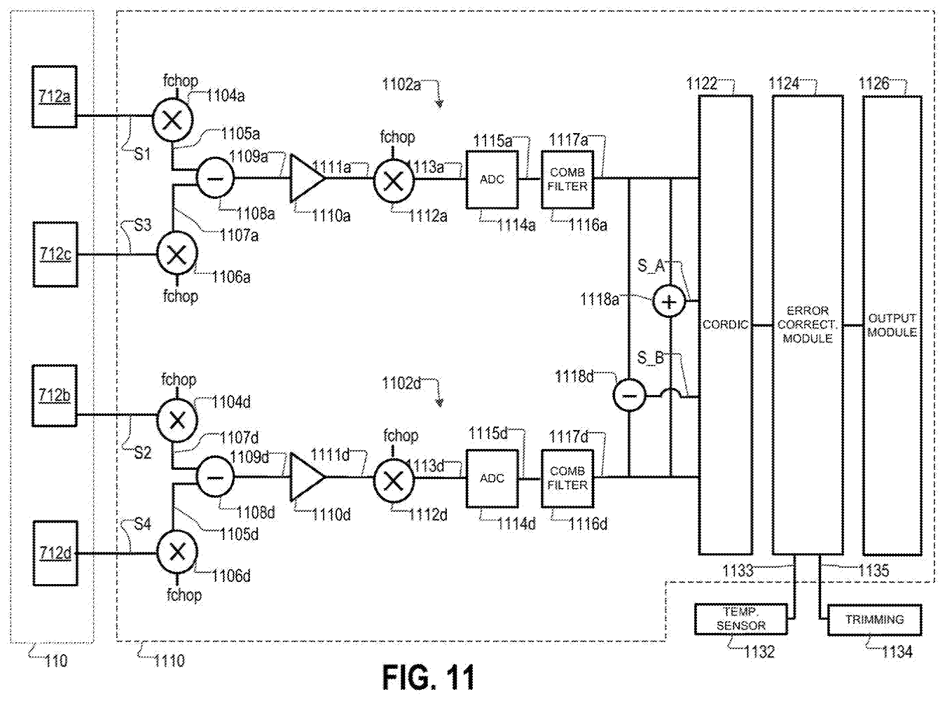

FIG. 11 is a circuit diagram of a processing circuitry 1110 that is used in conjunction with the sensor 110. The processing circuitry 1110 may include a processing path 1102a and a processing path 1102d. The processing path 1102a may be arranged to process signals that are generated by the planar Hall elements 712a and 712c and the processing path 1102d may be arranged to process signals that are generated by the planar Hall elements 712b and 712d.

The planar Hall element 712a may generate a signal S1 that is subsequently provided to a modulator 1104a. The modulator 1104a may modulate the signal S1 based on a frequency fchop to produce a modulated signal 1105a. The planar Hall element 712c may generate a signal S3 that is subsequently provided to a modulator 1106a. The modulator 1106a may modulate the signal S3 based on the frequency fchop to produce modulated signal 1107a. A subtractor 1108a may subtract the modulated signal 1107a from the modulated signal 1107a to produce a signal 1109a, which is subsequently provided to an amplifier 1110a. As can be readily appreciated, subtracting the two signals from one another may cancel out the effects of stray magnetic fields that are incident on the planar Hall elements 712a and 712c, resulting in a signal 1109a that is stray field immune. The amplifier 1110a may amplify the signal 1109a to produce an amplified signal 1111a, which is subsequently provided to a demodulator 1112a. The demodulator 1112a may demodulate the amplified signal 1113a based on the frequency fchop to produce a demodulated signal 1113a, which is subsequently provided to an analog-to-digital converter (ADC) 1114a. The ADC 1114a may digitize the demodulated signal 1113a to produce a digital signal 1115a, which is subsequently provided to a filter 1116a, such as a comb filter. The comb filter 1116a may filter the digital signal 1115a to produce a filtered signal 1117a, which is subsequently provided to a CORDIC module 1122.

The planar Hall element 712b may generate a signal S2 that is subsequently provided to a modulator 1104a. The modulator 1104d may modulate the signal S2 based on a frequency fchop to produce a modulated signal 1105a. The planar Hall element 712d may generate a signal S4 that is subsequently provided to a modulator 1106a. The modulator 1106d may modulate the signal S4 based on the frequency fchop to produce modulated signal 1107d. A subtractor 1108d may subtract the modulated signal 1107d from the modulated signal 1105d to produce a signal 1109d, which is subsequently provided to an amplifier 1110d. As can be readily appreciated, subtracting the two signals from one another may cancel out the effects of stray magnetic fields that are incident on the planar Hall elements 712b and 712d, resulting in a signal 1109d that is immune to stray fields. The amplifier 1110d may amplify the signal 1109d to produce an amplified signal 1111d, which is subsequently provided to a demodulator 1112a. The demodulator 1112d may demodulate the amplified signal 1113d based on the frequency fchop to produce a demodulated signal 1113a, which is subsequently provided to an analog-to-digital converter (ADC) 1114a. The ADC 1114d may digitize the demodulated signal 1113d to produce a digital signal 1115d, which is subsequently provided to a comb filter 1116d. The comb filter 1116d may filter the digital signal 1115d to produce a filtered signal 1117a, which is subsequently provided to a CORDIC module 1122. A summation element 1118a may add the signals 1117a and 1117d to produce a signal S_A, which is subsequently provided to the CORDIC module. A summation element 1118d may add the subtract the signal 1117d from the signal 1117a to produce a signal S_B, which is subsequently provided to the CORDIC module.

The CORDIC module 1122 may include any suitable type of processing circuitry that is configured to execute a Coordinate Rotation Digital Computer (CORDIC) algorithm or otherwise compute an arctangent function (e.g., such as by using a look-up table). According to the example of FIG. 11, the CORDIC module is configured to calculate a raw position signal based on the signals S_A and S_B. The raw position signal may identify the angular position and/or speed of rotation of the ring magnet 720 relative to the sensor 710. In some implementations, the raw position signal may be calculated in accordance with Equation 9 below:

$${S}_{raw} = arctan ( \frac{S\_A}{S\_B} ) \qquad ( Eq . 9 )$$

where S_{raw} is the raw position signal.

The error correction module 1124 may include any suitable type of processing circuitry for adjusting the gain and/or offset of the raw position signal that is produced by the CORDIC module 1122. In operation, the error correction module 1124 may receive the raw position signal from the CORDIC module 1122 and generate an adjusted signal based on the received raw position signal. The adjusted signal may be generated by adjusting the gain and/or offset of the raw position signal. The gain and/or offset of the raw position signal may be adjusted, in a well-known fashion, based on a signal 1133 that is generated by a temperature sensor 1132. Additionally or alternatively, the gain and/or offset of the raw position signal may be adjusted based on a signal 1135 that is generated by a trim module 1134. The trim module 1134 may be a memory that is arranged to provide (to the error correction module) one or more coefficients for adjusting the gain and/or offset of the raw position signal. However, alternative implementations are possible in which the trim module 1134 includes another type of device (e.g., a humidity sensor, etc.) that is used for correcting the gain and/or offset of the raw position signal. Stated succinctly, the present disclosure is not limited to any specific method for adjusting the gain and/or offset of the raw position signal.

The output module 1126 may include any suitable type of communications interface for outputting the adjusted signal that is produced by the error correction module 1124. The output block may format the adjusted signal into a desired output signal format and provide the formatted signal to another device (e.g. an Engine Control Unit) that is coupled to the output module 1126. The desired format may be PWM format, Single Edge Nibble Transmission (SENT) format, a Serial Peripheral Interface (SPI) format, a Local Interconnect Network (LIN) format, a CAN (Controller Area Network) format, an Inter-Integrated Circuit (I²C) format to name a few non-limiting examples.

The processes described herein may be implemented in hardware, software, or a combination of the two. The processes described herein may be implemented in computer programs executed on programmable computers/machines that each includes a processor, a non-transitory machine-readable medium or another article of manufacture that is readable by the processor (including volatile and non-volatile memory and/or storage elements), at least one input device, and one or more output devices. Program code may be applied to data entered using an input device to perform any of the processes described herein and to generate output information.

The system may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, volatile memory, magnetic diskette and so forth but does not include a transitory signal per se.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. An apparatus, comprising:
a ring magnet having first surface, a second surface, and a bore extending from the first surface to the second surface, the bore having a central longitudinal axis;
a substrate disposed inside the bore of the ring magnet, the substrate having a first axis and a second axis that is orthogonal to the first axis, the first axis and the second axis being orthogonal to the central longitudinal axis of the bore;
a first group of magnetic field sensing elements that are formed on the substrate, the first group of magnetic field sensing elements including a first magnetic field sensing element and a second magnetic field sensing element, the first magnetic field sensing element being aligned with the first axis and the second magnetic field sensing element being aligned with the second axis; and
a second group of magnetic field sensing elements that are formed on the substrate, the second group of magnetic field sensing elements including a third magnetic field sensing element and a fourth magnetic field sensing element, the third magnetic field sensing element being aligned with the first axis, and the fourth magnetic field sensing element being aligned with the second axis.

2. The apparatus of claim 1, wherein the bore has a height and a width, and the substrate is centered in both the height and the width of the bore.

3. The apparatus of claim 1, wherein the first magnetic field sensing element is arranged to generate a first signal, the second magnetic field sensing element is arranged to generate a second signal, the third magnetic field sensing element is arranged to generate a third signal, and the fourth magnetic field sensing element is arranged to generate a fourth signal, the apparatus further comprising a processing circuit configured to generate an output signal indicating a position of the ring magnet, the output signal being generated based at least in part on: (i) a difference between the first signal and the third signal, and (ii) a difference between the second signal and the fourth signal.

4. The apparatus of claim 1, wherein each of the first magnetic field sensing element, the second magnetic field sensing element, the third magnetic field sensing element, and the fourth magnetic field sensing element is separated by a same distance from the central longitudinal axis of the bore.

5. The apparatus of claim 1, wherein the ring magnet includes an inner sidewall, and a distance between the central longitudinal axis of the bore and any given one of the first magnetic field sensing element, the second magnetic field sensing element, the third magnetic field sensing element, and the fourth magnetic field sensing element is larger than a distance between the inner sidewall and the given magnetic field sensing element.

6. The apparatus of claim 1, wherein the first group of magnetic field sensing elements and the second group of magnetic field sensing elements are formed on the substrate in an arrangement that is asymmetrical with respect to the central longitudinal axis of the bore.

7. The apparatus of claim 1, further comprising:
a third group of magnetic field sensing elements that are formed on the substrate, the third group of magnetic field sensing elements including a fifth magnetic field sensing element and a sixth magnetic field sensing element, the fifth magnetic field sensing element being aligned with the first axis and the sixth magnetic field sensing element being aligned with the second axis; and
a fourth group of magnetic field sensing elements that are formed on the substrate, the fourth group of magnetic field sensing elements including a seventh magnetic field sensing element and an eighth magnetic field sensing element, the seventh magnetic field sensing element being aligned with the first axis, and the eighth magnetic field sensing element being aligned with the second axis.

8. The apparatus of claim 7, wherein the first group of magnetic field sensing elements, the second group of magnetic field sensing elements, the third group of magnetic field sensing elements, and the fourth group of magnetic field sensing elements are disposed on the substrate in a pattern that is asymmetrical with respect to the central longitudinal axis of the bore.

9. The apparatus of claim 1, wherein each of the first magnetic field sensing element, the second magnetic field sensing element, and the third magnetic field sensing element, and the fourth magnetic field sensing element is formed on a periphery of the substrate.

10. An apparatus, comprising:
a substrate having a major planar surface, wherein the major planar surface has a first axis and a second axis that is orthogonal to the first axis;
a first group of magnetic field sensing elements that are formed on the major planar surface of the substrate, the first group of magnetic field sensing elements including a first magnetic field sensing element and a second magnetic field sensing element, the first magnetic field sensing element being aligned with the first axis and the second magnetic field sensing element being aligned with the second axis; and
a second group of magnetic field sensing elements that are formed on the major planar surface of the substrate, the second group of magnetic field sensing elements including a third magnetic field sensing element and a fourth magnetic field sensing element, the third magnetic field sensing element being aligned with the first axis, and the fourth magnetic field sensing element being aligned with the second axis,
wherein each of the first magnetic field sensing element, the second magnetic field sensing element, and the third magnetic field sensing element, and the fourth magnetic field sensing element is formed on a periphery of the substrate.

11. The apparatus of claim 10, further comprising a ring magnet having first surface, a second surface, and a bore extending from the first surface to the second surface, the bore having a longitudinal axis, wherein the first vertical group of magnetic field sensing elements and the second group of magnetic field sensing elements are formed on the major planar surface of the substrate in an arrangement that is asymmetrical with respect to a longitudinal axis of the bore.

12. The apparatus of claim 10, wherein a distance between any given one of the first magnetic field sensing element, the second magnetic field sensing element, the third magnetic field sensing element, the fourth magnetic field sensing element and edge of the substrate that is nearest to the given magnetic field sensing element is smaller than a distance between the given magnetic field sensing element and a center of the substrate.

13. The apparatus of claim 10, wherein the first magnetic field sensing element is arranged to generate a first signal, the second magnetic field sensing element is arranged to generate a second signal, the third magnetic field sensing element is arranged to generate a third signal, and the fourth magnetic field sensing element is arranged to generate a fourth signal, the apparatus further comprising a processing circuit configured to generate an output signal indicating a position of a target, the output signal being generated based at least in part on (i) a difference between the first signal and the third signal, and (ii) a difference between the second signal and the fourth signal.

14. An apparatus, comprising:
a substrate having a major planar surface, wherein the major planar surface has a first axis and a second axis that is orthogonal to the first axis;
a first planar Hall element that is formed on the first axis, the first planar Hall element being arranged to generate a first signal;
a second planar Hall element that is formed on the second axis, the second planar Hall element being arranged to generate a second signal;
a third planar hall element that is formed on the first axis, the third planar Hall element being arranged to generate a third signal; and
a fourth planar Hall element that is formed on the second axis, the fourth planar Hall element being arranged to generate a fourth signal; and
a processing circuit configured to: (i) generate a first combined signal based on the difference between the first and third signals and a difference between the second and fourth signals, and (ii) generate second combined signal based on a difference between the first and third signals and a difference between the fourth and second signals.

15. The apparatus of claim 14, wherein:
the first combined signal is generated in accordance with the equation of:
CS₁=S₁+S₂−S₃−S₄
where CS₁ is the first combined signal, S₁ is the first signal, S₂ is the second signal, S₃ is the third signal, and S₄ is the fourth signal.

16. The apparatus of claim 14, wherein:
the second combined signal is generated in accordance with the equation of:
CS₂=S₁−S₂−S₃+S₄
where CS₂ is the first combined signal, S₁ is the first signal, S₂ is the second signal, S₃ is the third signal, and S₄ is the fourth signal.

17. The apparatus of claim 14, wherein the processing circuit is further configured to generate an output signal indicating a position of a magnet based on the first combined signal and the second combined signal.

18. The apparatus of claim 14, further comprising a ring magnet having a first surface, a second surface, and a bore extending between the first surface and the second surface, wherein the substrate is disposed directly above or below the bore of the ring magnet.

19. The apparatus of claim 14, wherein the first planar Hall element, the second planar Hall element, the third planar Hall element, and the fourth planar Hall element are disposed in a pattern that is symmetrical with respect to an intersection of the first axis and the second axis.
